(19) United States
(12) Patent Application Publication
(10) Pub. No.: US 2013/0277194 A1
(43) Pub. Date: Oct. 24, 2013

(54) TOUCH PANEL

(71) Applicants: Youn Soo Kim, Gyunggi-do (KR); Ho Joon Park, Gyunggi-do (KR); Seung Min Lee, Gyunggi-do (KR); Ha Yoon Song, Gyunggi-do (KR); Sang Hwan Oh, Gyunggi-do (KR)

(72) Inventors: Youn Soo Kim, Gyunggi-do (KR); Ho Joon Park, Gyunggi-do (KR); Seung Min Lee, Gyunggi-do (KR); Ha Yoon Song, Gyunggi-do (KR); Sang Hwan Oh, Gyunggi-do (KR)

(73) Assignee: SAMSUNG ELECTRO-MECHANICS CO., LTD., Gyunggi-do (KR)

(21) Appl. No.: 13/542,404

(22) Filed: Jul. 5, 2012

(30) Foreign Application Priority Data
Apr. 24, 2012 (KR) 1020120042815

(51) Int. Cl. H03K 17/96

(52) U.S. Cl. 200/600

(57) ABSTRACT

Disclosed herein is a touch panel including: a transparent substrate; an electrode formed on the transparent substrate; and a visibility reducing layer having a width smaller than that of the electrode and interposed between the electrode and the transparent substrate.

### CROSS REFERENCE TO RELATED APPLICATION

This application claims the benefit of Korean Patent Application No. 10-2012-0042815, filed on Apr. 24, 2012, entitled “Touch Panel”, which is hereby incorporated by reference in its entirety into this application.

### BACKGROUND OF THE INVENTION

1. Technical Field

The present invention relates to a touch panel.

2. Description of the Related Art

In accordance with growth of a computer using a digital technology, devices assisting computers have also been developed, and a personal computer, a portable transmitter, other personal information processors, and the like, execute processing of text and graphics using various input devices such as a keyboard and a mouse.

However, according to rapid advancement of an information-oriented society, since use of computers has been increasingly expanded, it is difficult to efficiently operate a product using only the keyboard and the mouse currently serving as the input device. Therefore, necessity for a device which is simple, has a minimal malfunction, and is capable of easily inputting information has increased.

Furthermore, a technique of the input device exceeds the level of fulfilling general functions and thus is progressing towards techniques related to high reliability, durability, innovation, designing and manufacturing. To this end, a touch panel has been developed as an input device capable of inputting information such as text and graphics.

The touch panel is mounted on a display surface of an image display device such as an electronic organizer, a flat panel display including a liquid crystal display (LCD), a plasma display panel (PDP), an electroluminescence (El) element or the like, or a cathode ray tube (CRT), so that a user selects the information desired while viewing the image display device.

The touch panel is classified into a resistive type, a capacitive type, an electromagnetic type, a surface acoustic wave (SAW) type, and an infrared type. These various types of touch panels are adapted for an electronic product in consideration of a signal amplification problem, a resolution difference, the degree of difficulty of designing and processing technologies, an optical characteristic, an electrical characteristic, a mechanical characteristic, resistance to an environment, an input characteristic, durability, and economical efficiency. Currently, the resistive type touch panel and the capacitive type touch panel have been prominently used in a wide range of fields.

In the touch panel of the prior art, a sensing electrode is made of indium tin oxide (ITO). However, the ITO has excellent electrical conductivity but is expensive since indium used as a raw material thereof is a rare earth metal. In addition, the indium is expected to be depleted within the next decade, such that it may not be smoothly supplied.

Meanwhile, in the touch panel, research into a technology of forming the electrode using a metal as disclosed in Korean Patent Laid-Open Publication No. 10-2010-0091497 has been actively conducted. In the case in which the electrode is made of a metal, it is advantageous in that the metal has electric conductivity significantly higher than that of the ITO and may be smoothly supplied. However, in the touch panel having the electrode as described above, the glitter may be generated in the electrode in the case in which the electrode is visually recognized, or light is irradiated from an outer portion to the electrode to thereby deteriorate visibility of the touch panel.

### SUMMARY OF THE INVENTION

The present invention has been made in an effort to provide a touch panel capable of solving a problem that an electrode made of a metal is visually recognized and preventing light reflection on the electrode to improve visibility.

According to a preferred embodiment of the present invention, there is provided a touch panel including: a transparent substrate; an electrode formed on the transparent substrate; and a visibility reducing layer having a width smaller than that of the electrode and interposed between the electrode and the transparent substrate.

The touch panel may further include an insulating layer formed on the transparent substrate; and a lower electrode formed on the insulating layer.

The touch panel may further include a visibility reducing layer having a width smaller than that of the lower electrode and interposed between the lower electrode and the insulating layer.

The touch panel may further include a lower substrate, a lower electrode formed on the lower substrate, and an adhesive layer adhering the transparent substrate and the lower substrate to each other.

The touch panel may further include a visibility reducing layer having a width smaller than that of the lower electrode and laminated on the lower electrode.

The visibility reducing layer may have a refractive index of 1.2 to 1.45.

The visibility reducing layer may be made of any one selected from a group consisting of an acryl based resin, a carbonate based resin, and a urethane based resin.

The visibility reducing layer may be made of any one selected from a group consisting of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), and biaxially oriented polystyrene (BOPS; containing K resin).

The visibility reducing layer may be made of any one selected from a group consisting of titanium dioxide (TiO₂), silicone dioxide (SiO₂), aluminum oxide (Al₂O₃), magnesium fluoride (MgF₂), cerium oxide (CeO₂), and niobium pentaoxide (Nb₂O₅).

The visibility reducing layer may have a width corresponding to ½ of that of the electrode.

The visibility reducing layer may be positioned at the center of the width of the electrode.

The electrode may be made of any one selected from copper (Cu), aluminum (Al), gold (Au), silver (Ag), titanium (Ti), palladium (Pd), and chromium (Cr), or a combination thereof.

The electrode may be made of metal silver formed by exposing and developing a silver salt emulsion layer.

According to another preferred embodiment of the present invention, there is provided a touch panel including: a transparent substrate, an electrode formed on one surface of the transparent substrate, and a visibility reducing layer having a width smaller than that of the electrode and laminated on the electrode.

The touch panel may further include a lower electrode formed on the other surface of the transparent substrate.

The touch panel may further include a visibility reducing layer having a width smaller than that of the lower electrode and interposed between the lower electrode and the transparent substrate.

The touch panel may further include a visibility reducing layer having a width smaller than that of the lower electrode and laminated on the lower electrode.

The visibility reducing layer may have a refractive index of 1.2 to 1.45.

The visibility reducing layer may be made of any one selected from a group consisting of an acryl based resin, a carbonate based resin, and a urethane based resin.

The visibility reducing layer may be made of any one selected from a group consisting of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), and biaxially oriented polystyrene (BOPS; containing K resin).

The visibility reducing layer may be made of any one selected from a group consisting of titanium dioxide (TiO₂), silicone dioxide (SiO₂), aluminum oxide (Al₂O₃), magnesium fluoride (MgF₂), cerium oxide (CeO₂), and niobium pentaoxide (Nb₂O₅).

The visibility reducing layer may have a width corresponding to ½ of that of the electrode.

The visibility reducing layer may be positioned at the center of the width of the electrode.

The electrode may be made of any one selected from copper (Cu), aluminum (Al), gold (Au), silver (Ag), titanium (Ti), palladium (Pd), and chromium (Cr), or a combination thereof.

The electrode may be made of metal silver formed by exposing and developing a silver salt emulsion layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a touch panel according to a first preferred embodiment of the present invention;

FIG. 2 is a plan view of the touch panel shown in FIG. 1;

FIG. 3 is a cross-sectional view of a touch panel according to a second preferred embodiment of the present invention;

FIG. 4 is a cross-sectional view of a touch panel according to a third preferred embodiment of the present invention;

FIG. 5 is a cross-sectional view of a touch panel according to a fourth preferred embodiment of the present invention; and

FIG. 6 is a cross-sectional view of a touch panel according to a fifth preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

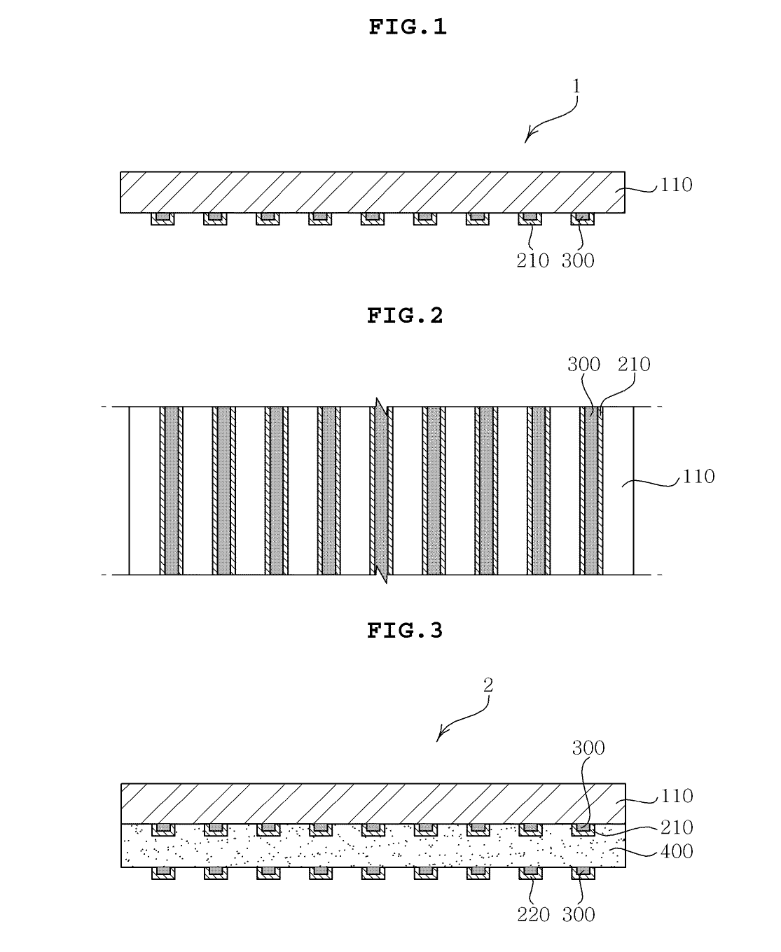

FIG. 1 is a cross-sectional view of a touch panel according to a first preferred embodiment of the present invention; and FIG. 2 is a plan view of the touch panel shown in FIG. 1.

As shown in FIGS. 1 and 2, the touch panel 1 according to the first preferred embodiment of the present invention includes a transparent substrate 110, an electrode 210 formed on the transparent substrate 110, and a visibility reducing layer 300 having a width smaller than that of the electrode 210 and formed so as to be interposed between the electrode 210 and the transparent substrate 110.

The transparent substrate 110 provides a region in which the electrode 210 will be formed. Here, the transparent substrate 110 needs to have support force capable of supporting the electrode 210, and transparency capable of allowing a user to recognize an image provided by an image display device.

In consideration of the support force and the transparency described above, the transparent substrate 110 may be made of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, tempered glass, or the like. However, the transparent substrate 110 is not limited thereto.

In the preferred embodiments of the present invention, one surface of the transparent substrate 110 is treated by a high-frequency processing or a primer processing to be activated. One surface of the transparent substrate 110 is treated as described above, thereby making it possible to significantly improve adhesion between the transparent substrate 110 and the electrode 210 to be formed on one surface of the transparent substrate 110 and to be described below.

Meanwhile, in the preferred embodiments of the present invention, the transparent substrate 110 may be a window provided at the outermost side of the touch panel 1. In the case in which the transparent substrate 110 is the window, the electrode 210 to be described below is directly formed on the window. In this case, a process of manufacturing the touch panel may omit a process of forming the electrode on a separate transparent substrate and then attaching it on the window; such that the entire thickness of the touch panel may be decreased.

The electrode 210 serves to generate a signal at the time of a touch by a user to allow a controller (not shown) to recognize a touch coordinate.

The electrode 210 is formed on one surface of the transparent substrate 110. The electrode 210 may be made of any one selected from copper (Cu), aluminum (Al), gold (Au), silver (Ag), titanium (Ti), palladium (Pd), and chromium (Cr), or a combination thereof. Here, the electrode 210 may be formed by a plating process or a depositing process. The electrode 210 may also be made of metal silver formed by exposing and developing a silver salt emulsion layer, in addition to the metal as described above. The electrode 210 made of the material as described above is formed in a mesh pattern on one surface of the transparent substrate 110, thereby making it possible to decrease surface resistance.

Meanwhile, the surface of the electrode 210 may be black-oxide treated in the case in which the electrode 210 is made of copper (Cu). Here, the black-oxide treatment is to precipitate Cu₂O or CuO by oxidizing the surface of the electrode 210, wherein the Cu₂O is brown and is thus referred to as a brown oxide and the CuO is black and is thus referred to as a black oxide. The electrode 210 is black-oxide treated as described above, thereby making it possible to prevent light reflection on the electrode 210 even though the light is irradiated to the electrode 210 through the transparent substrate 110. Accordingly, the visibility of the touch panel may be improved. However, in the black-oxide treated touch panel, since the portion of the black-oxide treated touch panel itself may be visibly recognized, the visibility is not improved as expected, and electrical characteristics of the electrode 210 are deteriorated due to the black-oxide treatment. Therefore, the touch panel according to the present embodiment includes the visibility reducing layer 300 minimizing the viewed portion of the electrode 210 and preventing the light reflection on the electrode 210 without performing the black-oxide treatment on the electrode 210.

The visibility reducing layer 300 is interposed between the electrode 210 and the transparent substrate 110. The visibility reducing layer 300 is interposed between the electrode 210 and the transparent substrate 110 to cover the electrode 210 with respect to the transparent substrate 110. However, the visibility reducing layer 300 does not cover the entire electrode 210. In the case in which the touch panel 1 according to the present embodiment is applied to the large screen, the electrode 210 needs to have significantly large width in order to secure high conductivity. For example, in the case in which screen size of the device applying the touch panel 1 according to the present embodiment is 10 inches or more, the case in which the electrode 210 is formed in a mesh pattern made of the metal as described above, line width of the electrode 210 needs to be 10 μm or more, thereby making it possible to obtain a desired touch sensibility while securing low resistance of the electrode 210. In addition, in the case in which the screen size is 23 inches or larger, and the case in which the electrode 210 is formed in the mesh pattern made of the metal as described above, the line width of the electrode 210 needs to be 15 μm or more. In the case in which the electrode 210 has a wide width of 10 μm or more, or 15 μm or more as described above, and the case in which the visibility reducing layer 300 covers the entire electrode 210 while having the same width as the line width of the electrode 210, the visibility reducing layer 300 itself may be viewed through the transparent substrate 110. Therefore, the visibility reducing layer 300 according to the present embodiment is formed so as to have a width smaller than that of the electrode 210. That is, the visibility reducing layer 300 is formed so that the visibility reducing layer 300 itself has the width having a range that is not visibly recognized. Specifically, in the case in which the line width of the electrode 210 is 10 μm or more, or 15 μm or more as described above, the width of the visibility reducing layer 300 may be 5 μm or more, or 7.5 μm or more so as to be ½ of that of the electrode 210. In this case, the visibility reducing layer 300 may be positioned at the center of the width of the electrode 210 and be formed along a length direction of the electrode 210 as shown in FIGS. 1 and 2. The visibility reducing layer 300 is formed to have a width corresponding to ½ of that of the electrode 210, and the visibility reducing layer 300 is positioned at the center of the width of the electrode 210, such that a portion of the electrode 210 at the width corresponding to ¼ of the entire width of the electrode 210 is exposed at each of the left and the right of the visibility reducing layer 300 through the transparent substrate 110. Therefore, the visibility reducing layer 300 has the width described above and is formed at the position described above, thereby making it possible to significantly reduce the visibility of the electrode 210. In addition, the electrode 210 is maximally covered by the visibility reducing layer 300, such that the light reflection phenomenon at the electrode 210 is decreased. Therefore, the touch panel 1 according to the present embodiment may have improved visibility by the visibility reducing layer 300.

Meanwhile, the visibility reducing layer 300 as described above is preferably made of a material having a refractive index lower than that of window glass provided at the outermost portion of the touch panel so that it may increase reflexibility thereof to cover the electrode 210. Specifically, the visibility reducing layer 300 has preferably the low refractive index of 1.2 to 1.45, which is less than a refractive index of glass (1.5). As a specific material of the visibility reducing layer 300 having the refractive index as described above, a material including an acryl based resin may be used. An example of the acryl based resin includes acrylate monomer, urethane acrylate oligomer, epoxy acrylate oligomer, ester acrylate oligomer, or the like, and more specifically, dipentaerythritolhexaacrylate, pendaerythritol tri/tetra acrylate, trimethylenepropantriacrylate, ethyleneglycoldiacrylate, or the like, which is not limited thereto. In addition, the visibility reducing layer 300 may include a carbonate based resin or a urethane based resin.

Alternatively, the visibility reducing layer 300 may be made of any one selected from a group consisting of polyethylene, polyethyleneterephthalate (PET), polypropylene, polymethylmethacrylate (PMMA), polyethylenenaphthalate (PEN), polyethersulfone (PES), cyclic olefin copolymer (COC), to triacetylcellulose (TAC), polyvinyl alcohol (PVA), polyimide (PI), polystyrene (PS), and biaxially oriented polystyrene (BOPS; containing K resin).

Meanwhile, all the material as described above is an organic material, which is not necessarily limited thereto. The visibility reducing layer 300 may be made of an inorganic material including any one selected from a group consisting of titanium dioxide (TiO₂), silicone dioxide (SiO₂), aluminum oxide (Al₂O₃), magnesium fluoride (MgF₂), cerium oxide (CeO₂), and niobium pentaoxide (Nb₂O₅).

FIG. 3 is a cross-sectional view of a touch panel according to a second preferred embodiment of the present invention.

The touch panel 2 according to the second preferred embodiment of the present invention further includes an insulating layer 400 formed on the transparent substrate 110, and a lower electrode 220 formed on the insulating layer 400 as compared to that of the first preferred embodiment of the present invention. Hereinafter, a portion overlapped with the description of the first preferred embodiment of the present invention will be omitted, and a portion different from the description of the first preferred embodiment of the present invention will be mainly described.

Meanwhile, the electrode recognizing the touch of the user may be formed of a sensing electrode and a driving electrode. Here, the sensing electrode and the driving electrode may be formed together on one surface of the transparent substrate 110, or be separately formed. The present embodiment describes an example in which the sensing electrode and the driving electrode are separately formed. The electrode 210 formed on the transparent substrate 110 may be the sensing electrode, and the lower electrode 220 formed on the insulating layer 400 may be the driving electrode.

The insulating layer 400 serves to protect the electrode 210 positioned at an upper portion thereof and provide a region in which the lower electrode 220 will be formed. The insulating layer 400 is formed on one surface of the transparent substrate 110 so as to cover the electrode 210. Here, the insulating layer 400 may be made of an epoxy based or an acrylic based resin, a SiOx thin film, or a SiNx thin film, or the like. In addition, the insulating layer 400 may be formed by printing, chemical vapor deposition (CVD), sputtering, or the like.

The lower electrode 220 is formed on one surface of the insulating layer 400. The lower electrode 220 may be formed in the mesh pattern and be made of any one selected from a group consisting of copper (Cu), aluminum (Al), gold (Au), silver (Ag), titanium (Ti), palladium (Pd), and chromium (Cr), or a combination thereof, or be made of metal silver formed by exposing and developing the silver salt emulsion layer, like the electrode 210 positioned at the upper portion of the insulating layer 400.

Alternatively, the lower electrode 220 may be formed in a surface shape at the insulating layer 400 while being made of a conductive polymer or a metal oxide. The conductive polymer has excellent flexibility and a simple coating process. The conductive polymer may include poly-3,4-ethylenedioxythiophene/polystyrenesulfonate (PEDOT/PSS), polyaniline, polyacetylene or polyphenylenevinylene. In addition, the metal oxide may be made of indium-thin oxide (ITO). The lower electrode 220 made of the material as described above may be formed by a dry process, a wet process, or a direct patterning process on the insulating layer 400. Here, the dry process refers to sputtering, evaporation, or the like, and the wet process refers to a dip coating, a spin coating, a roll coating, a spray coating, or the like, and the direct patterning process refers to screen printing, gravure printing, inkjet printing, or the like.

Meanwhile, in the case in which the lower electrode 220 is made of the metal as described above and is formed in the mesh pattern, the visibility reducing layer 300 may be formed corresponding to the lower electrode 220. The visibility reducing layer 300 formed corresponding to the lower electrode 220 is formed so as to have the width smaller than that of the lower electrode 220, and is formed so as to be interposed between the lower electrode 220 and the insulating layer 400.

In the touch panel 2 according to the present embodiment, the visibility reducing layer 300 corresponding to the lower electrode 220 is formed, such that the lower electrode 220, as well as the electrode 210 positioned at the upper portion of the insulating layer 400, also has the minimum portion exposed through the transparent substrate 110. In addition, the light reflection phenomenon capable of being generated in the lower electrode 220 may be decreased.

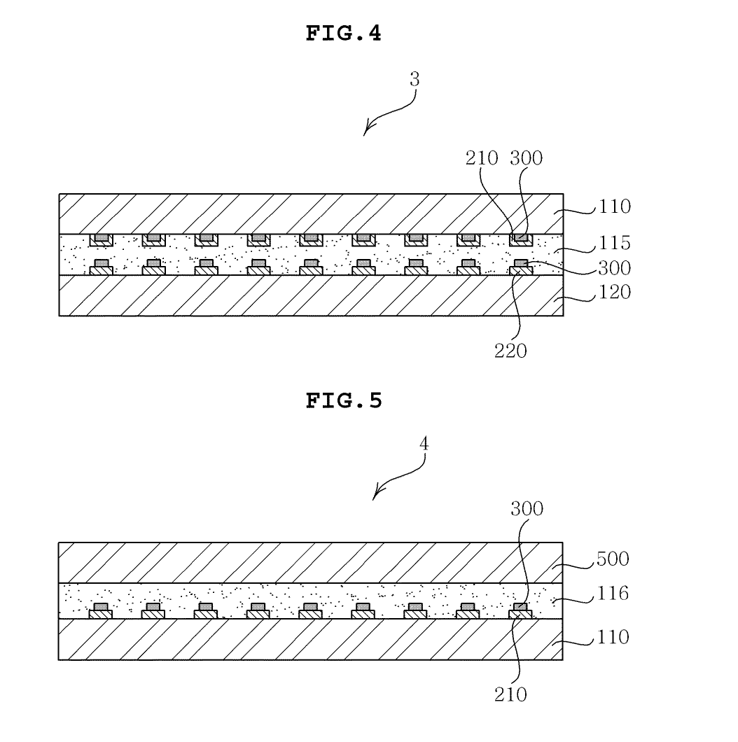

FIG. 4 is a cross-sectional view of a touch panel according to a third preferred embodiment of the present invention.

The touch panel 3 according to the second preferred embodiment of the present invention further includes a lower substrate 120, a lower electrode 220 formed on the lower substrate 120, and an adhesive layer 115 adhering the transparent substrate 110 and the lower substrate 120 to each other as compared to that of the first preferred embodiment of the present invention. Therefore, hereinafter, a portion overlapped with the description of the first preferred embodiment of the present invention will be omitted, and a portion different from the description of the first preferred embodiment of the present invention will be mainly described.

The lower substrate 120 may be made of polyethylene terephthalate (PET), polycarbonate (PC), poly methyl methacrylate (PMMA), polyethylene naphthalate (PEN), polyethersulpone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing a K resin), glass, tempered glass, or the like, so as to have support force and transparency, similar to the transparent substrate 110. Meanwhile, the lower substrate 120 is not necessarily limited thereto.

One surface of the lower substrate 120 may be activated through frequency treatment of primer treatment. One surface of the lower substrate 120 is treated as described above, thereby making to it possible to further improve the adhesion between the lower substrate 120 and a lower electrode 220 to be described below to be formed on one surface of the lower substrate 120.

The lower electrode 220 is formed on one surface of the lower substrate 120. The lower electrode 220 may be formed in the mesh pattern and be made of any one selected from a group consisting of copper (Cu), aluminum (Al), gold (Au), silver (Ag), titanium (Ti), palladium (Pd), and chromium (Cr), or a combination thereof, or be made of metal silver formed by exposing and developing the silver salt emulsion layer, like the electrode 210 positioned at the upper portion of the insulating layer 400. Alternatively, the lower electrode 220 may have a surface shape while being made of a conductive polymer or a metal oxide. Other descriptions regarding the lower electrode 220 may be supplemented by the description regarding the lower electrode 220 of the secondary preferred embodiment of the present invention.

Meanwhile, in the case in which the lower electrode 220 is made of the metal as described above and is formed in the mesh pattern, the visibility reducing layer 300 may be formed corresponding to the lower electrode 220. The visibility reducing layer 300 formed corresponding to the lower electrode 220 has the width smaller than that of the lower electrode 220, and is laminated on the lower substrate 120 so that the lower electrode 220 is covered with respect to the transparent substrate 110. In the touch panel 3 according to the present embodiment, the visibility reducing layer 300 corresponding to the lower electrode 220 is formed, such that the lower electrode 220, as well as the electrode 210 positioned at the upper portion of the insulating layer 400, also has the minimum portion exposed through the transparent substrate 110. In addition, the light reflection phenomenon capable of being generated in the lower electrode 220 may be decreased.

The adhesive layer 115 serves to adhere one surface of the transparent substrate 110 and one surface of the lower substrate 120 to each other. An example of the adhesive layer 115 includes optical clear adhesive (OCA), but is not specifically limited thereto.

FIG. 5 is a cross-sectional view of a touch panel according to a fourth preferred embodiment of the present invention.

The touch panel 4 according to the fourth preferred embodiment of the present invention includes a transparent substrate 110, an electrode 210 formed on one surface of the transparent substrate 110, and a visibility reducing layer 300 having a width smaller than that of the electrode 210 and formed so as to be laminated on the electrode 210.

In the touch panel 4 according to the present embodiment, the visibility reducing layer 300 is formed so as to be laminated on the electrode 210 as compared to that of the first preferred embodiment of the present invention. The visibility reducing layer 300 is formed so as to be laminated on the electrode 210 in order to cover the electrode 210 with respect to the transparent substrate 110, which is similar to the case in which the visibility reducing layer 300 is laminated on the lower electrode 220 according to the third preferred embodiment of the present invention.

Meanwhile, the present embodiment may further include a window 500 attached on the transparent substrate 110.

The window 500 is provided at the outermost side of the touch panel 4 to thereby protect an inner configuration like the electrode 210. In addition, the window 500 is also a member on which the touch by an input unit directly acts. Here, a material of the window 500 is not specifically limited thereto. The window 500 may be formed of glass, tempered glass, or the like. The window 500 may be attached on the transparent substrate 110 using the optical clear adhesive (OCA) 116, or the like.

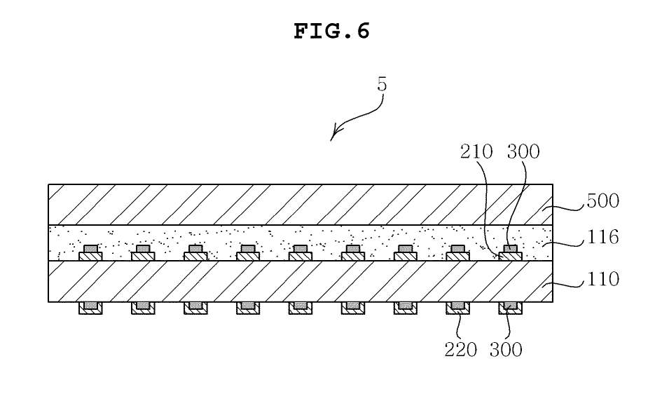

FIG. 6 is a cross-sectional view of a touch panel according to a fifth preferred embodiment of the present invention.

The touch panel 5 according to the present embodiment further includes the lower electrode 220 formed on other surface of the transparent substrate 110 as compared to that of the fourth preferred embodiment of the present invention. Therefore, hereinafter, a portion overlapped with the description of the fourth preferred embodiment of the present invention will be omitted, and a portion different from the description of the fourth preferred embodiment of the present invention will be mainly described.

The lower electrode 220 is formed on other surface of the transparent substrate 110. The lower electrode 220 may be formed in the mesh pattern and be made of any one selected from a group consisting of copper (Cu), aluminum (Al), gold (Au), silver (Ag), titanium (Ti), palladium (Pd), and chromium (Cr), or a combination thereof, or be made of metal silver formed by exposing and developing the silver salt emulsion layer, like the electrode 210 positioned at the upper portion of the insulating layer 400. Otherwise, the lower electrode 220 may have a surface shape while being made of a conductive polymer or a metal oxide. Other descriptions regarding the lower electrode 220 may be supplemented by the description regarding the lower electrode 220 of the secondary preferred embodiment of the present invention.

Meanwhile, in the case in which the lower electrode 220 is formed in the mesh pattern and is made of the metal as described above, the visibility reducing layer 300 may be formed corresponding to the lower electrode 220. The visibility reducing layer 300 formed corresponding to the lower electrode 220 is formed so as to have the width smaller than that of the lower electrode 220, and is formed so as to be interposed between the lower electrode 220 and the lower substrate 120 so that the lower electrode 220 is covered with respect to the transparent substrate 110. In the touch panel 5 according to the present embodiment, the visibility reducing layer 300 corresponding to the lower to electrode 220 is formed, such that the lower electrode 220, as well as the electrode 210 positioned at the upper portion of the insulating layer 400, also has the minimum portion exposed through the transparent substrate 110. In addition, the light reflection phenomenon capable of being generated in the lower electrode 220 may be decreased.

As set forth above, according to the preferred embodiments of the present invention, the visibility reducing layer is included to minimize the portion of the electrode exposed to the outside and prevent the light reflection on the electrode, thereby making it possible to improve the visibility.

Particularly, in the case in which the touch panel according to the preferred embodiment of the present invention is applied to the device having a large screen, for example, in the case in which the metal electrode is formed to have the line width of 10 μm or more, the visibility reducing layer minimizes the exposed portion of the electrode and is not viewed on its own, thereby making it possible to improve the visibility of the touch panel.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel comprising:
a transparent substrate;
an electrode formed on the transparent substrate; and
a visibility reducing layer having a width smaller than that of the electrode and interposed between the electrode and the transparent substrate.

2. The touch panel as set forth in claim 1, further comprising:
an insulating layer formed on the transparent substrate; and
a lower electrode formed on the insulating layer.

3. The touch panel as set forth in claim 2, further comprising:
a visibility reducing layer having a width smaller than that of the lower electrode and interposed between the lower electrode and the insulating layer.

4. The touch panel as set forth in claim 1, further comprising:
a lower substrate,
a lower electrode formed on the lower substrate, and
an adhesive layer adhering the transparent substrate and the lower substrate to each other.

5. The touch panel as set forth in claim 4, further comprising:
a visibility reducing layer having a width smaller than that of the lower electrode and laminated on the lower electrode.

6. The touch panel as set forth in claim 1, wherein the visibility reducing layer has a refractive index of 1.2 to 1.45.

7. The touch panel as set forth in claim 1, wherein the visibility reducing layer is made of any one selected from a group consisting of an acryl based resin, a carbonate based resin, and a urethane based resin.

8. The touch panel as set forth in claim 1, wherein the visibility reducing layer is made of any one selected from a group consisting of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), and biaxially oriented polystyrene (BOPS; containing K resin).

9. The touch panel as set forth in claim 1, wherein the visibility reducing layer is made of any one selected from a group consisting of titanium dioxide (TiO₂), silicone dioxide (SiO₂), aluminum oxide (Al₂O₃), magnesium fluoride (MgF₂), cerium oxide (CeO₂), and niobium pentaoxide (Nb₂O₅).

10. The touch panel as set forth in claim 1, wherein the visibility reducing layer has a width corresponding to ½ of that of the electrode.

11. The touch panel as set forth in claim 1, wherein the visibility reducing layer is positioned at the center of the width of the electrode.

12. A touch panel comprising:
a transparent substrate,
an electrode formed on one surface of the transparent substrate, and
a visibility reducing layer having a width smaller than that of the electrode and laminated on the electrode.

13. The touch panel as set forth in claim 12, further comprising:
a lower electrode formed on the other surface of the transparent substrate.

14. The touch panel as set forth in claim 13, further comprising:
a visibility reducing layer having a width smaller than that of the lower electrode and interposed between the lower electrode and the transparent substrate.

15. The touch panel as set forth in claim 12, wherein the visibility reducing layer has a refractive index of 1.2 to 1.45.

16. The touch panel as set forth in claim 12, wherein the visibility reducing layer is made of any one selected from a group consisting of an acryl based resin, a carbonate based resin, and a urethane based resin.

17. The touch panel as set forth in claim 12, wherein the visibility reducing layer is made of any one selected from a group consisting of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), and biaxially oriented polystyrene (BOPS; containing K resin).

18. The touch panel as set forth in claim 12, wherein the visibility reducing layer is made of any one selected from a group consisting of titanium dioxide (TiO₂), silicone dioxide (SiO₂), aluminum oxide (Al₂O₃), magnesium fluoride (MgF₂), cerium oxide (CeO₂), and niobium pentaoxide (Nb₂O₅).

19. The touch panel as set forth in claim 12, wherein the visibility reducing layer has a width corresponding to ½ of that of the electrode.

20. The touch panel as set forth in claim 12, wherein the visibility reducing layer is positioned at the center of the width of the electrode.
